(19) United States
(12) Patent Application Publication
(10) Pub. No.: US 2010/0006322 A1
(43) Pub. Date: Jan. 14, 2010

(54) Sim Card Structure

(75) Inventor: Meng-Jen Cheng, Taoyuan County (TW)

Correspondence Address: WPAT, PC;INTELLECTUAL PROPERTY ATTORNEYS, 2030 MAIN STREET, SUITE 1300, IRVINE, CA, 92614, US

(73) Assignee: Beautiful Card Corporation, Taoyuan County (TW)

(21) Appl. No.: 12/170,245

(22) Filed: Jul. 9, 2008

(51) Int. Cl. H05K 1/00

(52) U.S. Cl. 174/250

(57) ABSTRACT

In a SIM card structure, there are included a carrier substrate and a plurality of chips. The carrier substrate is provided at a central area with at least two parallelly arranged first weakening lines, and at two laterally opposite areas with a group of equally spaced second weakening lines each. The second weakening lines in each group are perpendicularly extended from one of the first weakening line toward one lateral edge of the carrier substrate, such that a plurality of card bodies is defined on the carrier substrate. Each of the card bodies is provided at a predetermined position with a receiving area for one of the chips to attach thereto and thereby forms a SIM card. Less material and storage room are needed for manufacturing and storing the card bodies, respectively. And, each of the SIM cards can be conveniently separated from the carrier substrate for use.

### FIELD OF THE INVENTION

The present invention relates to a SIM card structure, and more particularly to a SIM card structure, with which a plurality of independently separable card bodies is formed on a carrier substrate to reduce material and storing costs for SIM cards.

### BACKGROUND OF THE INVENTION

As can be seen from FIG. 1, a conventional SIM (subscriber identity module) card structure includes a card body 3 and a SIM card 4 cut out from but still attached to the card body 3 via a link portion 41 and a weakening line 42. To remove the SIM card 4 from the card body 3 for use, a force is applied on the SIM card 4 to separate the same from the link portion 41 and the weakening line 42.

There is only one SIM card 4 provided on the card body 3. When the SIM card 4 has been separated from the card body 3, the remained card body 3 is useless and forms a waste of material to increase the manufacturing cost of the SIM card. Moreover, when a plurality of the card bodies 3 are stacked for storage, as shown in FIG. 2, since there is only one SIM card 4 attached to each of the card bodies 3, a relatively large room is occupied by the stacked card bodies 3 while only a small number of SIM cards 4 is stored.

### SUMMARY OF THE INVENTION

A primary object of the present invention is to provide a SIM card structure, in which first and second weakening lines are formed on a carrier substrate to define a plurality of card bodies on the carrier substrate, such that the card bodies each can be conveniently separated from the carrier substrate for use. As a result, waste of material for manufacturing the card bodies can be avoided, and reduced room is required to store a large number of card bodies.

To achieve the above and other objects, the SIM card structure according to the present invention includes a carrier substrate and a plurality of chips. The carrier substrate is provided at a substantially central area with at least two parallelly arranged first weakening lines, and at two laterally opposite areas with a group of equally spaced second weakening lines each. The second weakening lines in each group are perpendicularly extended from one of the first weakening line toward one lateral edge of the carrier substrate, such that a plurality of card bodies is defined on the carrier substrate. Each of the card bodies is provided at a predetermined position with a receiving area for one of the chips to attach thereto and thereby forms a SIM card.

### BRIEF DESCRIPTION OF THE DRAWINGS

The structure and the technical means adopted by the present invention to achieve the above and other objects can be best understood by referring to the following detailed description of the preferred embodiments and the accompanying drawings, wherein

FIG. 1 is a perspective view showing a conventional SIM card structure;

FIG. 2 shows a plurality of SIM cards provided in the conventional SIM card structure being stacked for storage;

FIG. 3 is an exploded perspective view showing a SIM card structure according to a first embodiment of the present invention;

FIG. 4 is an assembled view of FIG. 3;

FIG. 5 shows a plurality of SIM cards provided in the SIM card structures of FIG. 4 being stacked for storage;

FIG. 6 shows the manner of separating one SIM card from a carrier substrate in the SIM card structure of FIG. 4;

FIG. 7 is a perspective view showing a SIM card structure according to a second embodiment of the present invention; and

FIG. 8 is a perspective view showing a SIM card structure according to a third embodiment of the present invention.

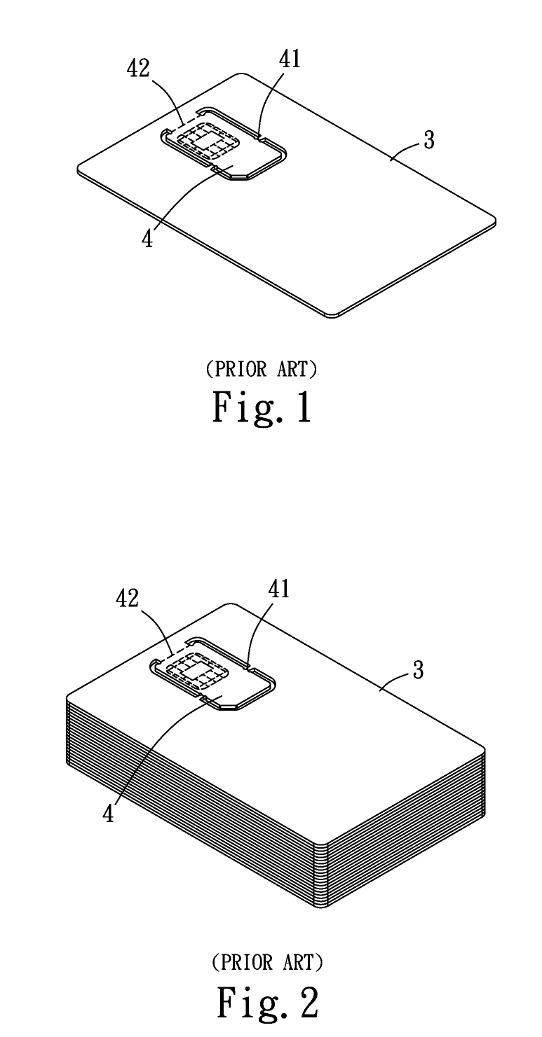

### DETAILED DESCRIPTION OF THE PREFERRED EMBODIMENTS

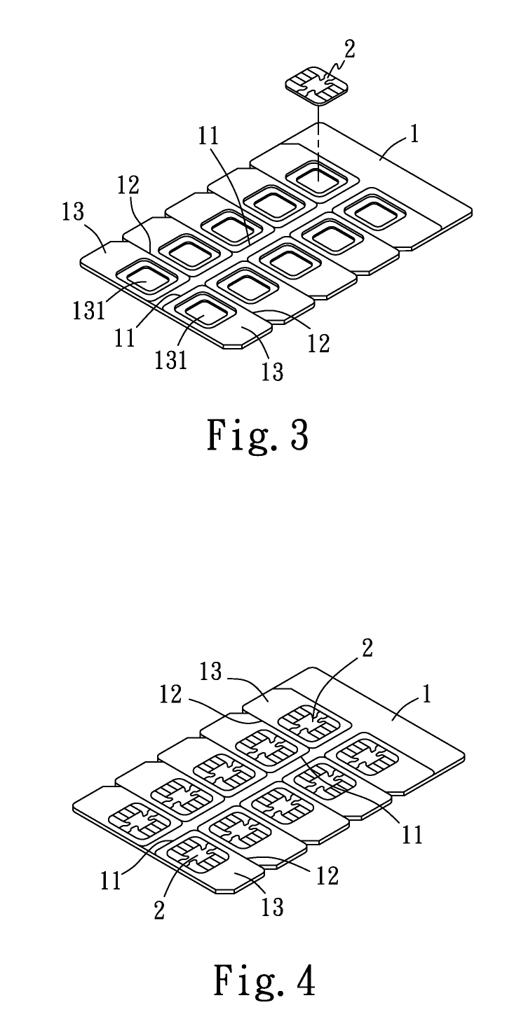

Please refer to FIGS. 3 and 4 that are exploded and assembled perspective views, respectively, showing a SIM card structure according to a first embodiment of the present invention. As shown, the SIM card structure includes a carrier substrate 1 and a plurality of chips 2.

The carrier substrate 1 is provided at a substantially central area thereof with at least two parallelly spaced first weakening lines 11, and at two laterally opposite areas thereof with a group of equally spaced second weakening lines 12 each. The second weakening lines 12 in each group are perpendicularly extended from one of the first weakening line 11 toward one lateral edge of the carrier substrate 1, such that a plurality of card bodies 13 is defined on the carrier substrate 1. Each of the card bodies 13 is provided at a predetermined position with a receiving area 131 for one of the chips 2 to attach thereto and thereby forms a SIM card.

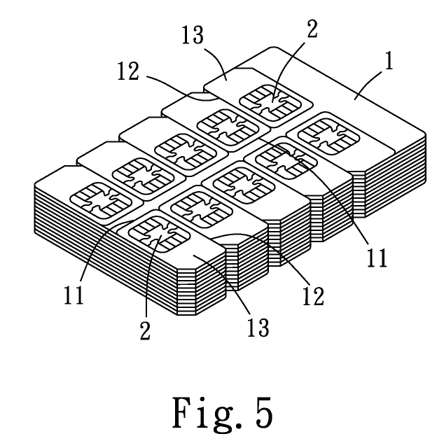

FIG. 5 is a perspective view showing a plurality of the SIM cards provided in the SIM card structure as shown in FIG. 4 are stacked for storage. Since every carrier substrate 1 in the stack includes a plurality of card bodies 13, and each of the card bodies 13 has a chip 2 attached thereto to form a SIM card, when the storage room is the same, the number of SIM cards according to the present invention that can be stacked for storing in the storage room is several times as much as that of the conventional SIM cards 4.

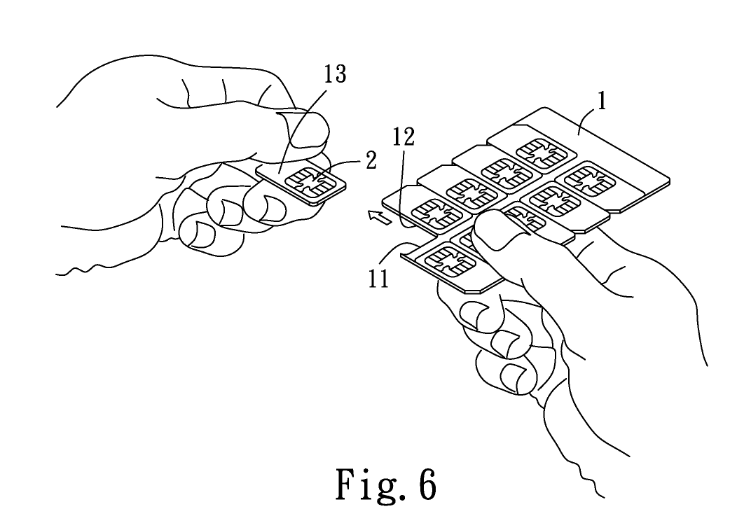

Please refer to FIG. 6. When it is desired to use one of the SIM cards on the carrier substrate 1, a user can simply hold the carrier substrate 1 with one hand and pinch one of the card bodies 13 with the other hand, and applies two forces in the same direction or in two opposite directions, so that the pinched card body 13 is separated from the carrier substrate 1 along the first and the second weakening lines 11, 12 adjacent to the card body 13. The SIM card formed by the separated card body 13 and the chip 2 attached thereto is now ready for use. All other card bodies 13 remaining on the carrier substrate 1 can still be safely stored.

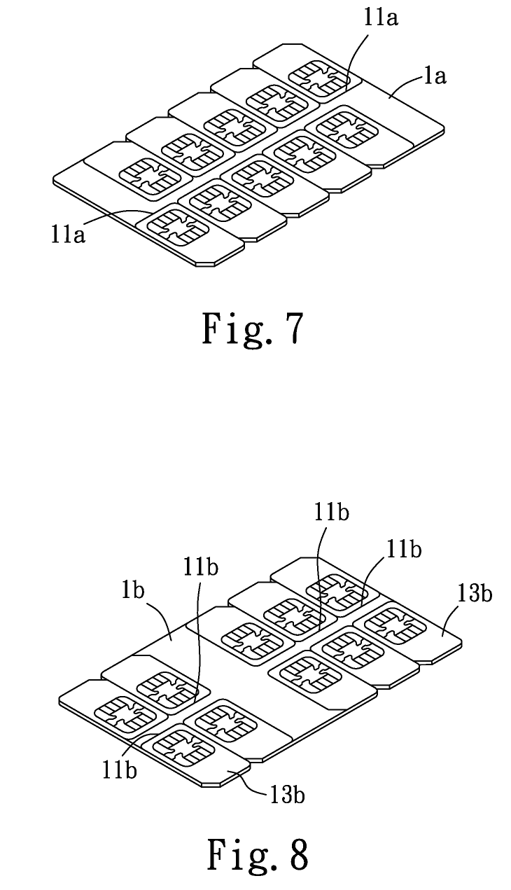

Please refer to FIG. 7 that is a perspective view showing a SIM card structure according to a second embodiment of the present invention. As shown, the SIM card structure in the second embodiment is similar to that in the first embodiment of the present invention, except that the second embodiment includes two parallel first weakening lines 11a arranged on a carrier substrate 1a in staggered relation.

FIG. 8 is a perspective view showing a SIM card structure according to a third embodiment of the present invention. As shown, the SIM card structure in the third embodiment is similar to that in the first embodiment of the present invention, except that the third embodiment includes two spaced groups of first weakening lines 11b arranged on a carrier substrate 1b closer to two opposite ends thereof, and each of the two groups includes two parallelly arranged first weakening lines 11b, such that two groups of a plurality of card bodies 13b are separately formed on the carrier substrate 1b closer to two opposite ends thereof, allowing a user to more conveniently hold the carrier substrate 1b near a middle portion thereof.

With the above arrangements, the SIM card structures according to different embodiments of the present invention effectively improve the prior art SIM card structure. With the provision of the first and the second weakening lines, a plurality of card bodies can be simultaneously formed on the carrier substrate to be independently separated from the carrier substrate for use. Therefore, less material and less storage room are needed for manufacturing and storing the card bodies, respectively, making the present invention novel, improved, and practical for use.

The present invention has been described with some preferred embodiments thereof and it is understood that many changes and modifications in the described embodiments can be carried out without departing from the scope and the spirit of the invention that is intended to be limited only by the appended claims.

What is claimed is:

1. A SIM card structure, comprising:
a carrier substrate being provided at a substantially central area thereof with at least two parallelly arranged first weakening lines, and at two laterally opposite areas thereof with a group of equally spaced second weakening lines each; the second weakening lines in each group being perpendicularly extended from one of the first weakening line toward one lateral edge of the carrier substrate, such that a plurality of card bodies are defined on the carrier substrate; and each of the card bodies being provided at a predetermined position with a receiving area; and
a plurality of chips being separately attached to the receiving areas on the card bodies.
